(19) United States
(12) Patent Application Publication
(10) Pub. No.: US 2026/0009835 A1
(43) Pub. Date: Jan. 8, 2026

(54) ELECTROMAGNETIC FIELD DETECTOR

(71) Applicant: British Telecommunications Public Limited Company, London (GB)

(72) Inventors: Amelia LEES, London (GB); Daniel GILKS, London (GB)

(21) Appl. No.: 19/127,913

(22) PCT Filed: Oct. 4, 2023
(86) PCT No.: PCT/EP2023/077380

§ 371 Date: May 7, 2025

(30) Foreign Application Priority Data
Nov. 8, 2022 (EP) 22206146.7

(51) Int. Cl. G01R 29/08

(52) U.S. Cl. CPC G01R 29/0885

(57) ABSTRACT

This invention provides a Rydberg-atom based electromagnetic field detector array comprising a plurality of Rydberg-atom based electromagnetic field detectors, wherein each Rydberg-atom based electromagnetic field detector is divided into a plurality of units, each unit of the plurality of units being either: a variable transparency unit configured to vary its transparency by the Electromagnetically Induced Transparency, EIT, effect and further vary its transparency in response to an incident electromagnetic field, or a separator unit, wherein a sequence of one or more variable transparency units and one or more separator units of the plurality of units for a Rydberg-atom based electromagnetic field detector uniquely identifies that Rydberg-atom based electromagnetic field detector in the Rydberg-atom based electromagnetic field detector array.

### PRIORITY CLAIM

The present application is a National Phase entry of PCT Application No. PCT/EP2023/077380, filed Oct. 4, 2023, which claims priority from EP application Ser. No. 22/206,146.7 filed Nov. 8, 2022, each of which hereby fully incorporated herein by reference.

### TECHNICAL FIELD

The present disclosure relates to a Rydberg-atom based electromagnetic field detector.

### BACKGROUND

A Rydberg atom is an atom with one or more electrons excited to a very high principal quantum number (e.g. >10). These Rydberg atoms have several useful properties, such as very large dipole moments and long decay periods.

The Rydberg atom may be used to detect an electromagnetic field. A Rydberg-atom based electromagnetic field detector is based on the Electromagnetically Induced Transparency (EIT) effect. The EIT effect may be experienced when a probe laser and a coupling laser are used to excite electrons of an atomic medium to a Rydberg state (that is, an elevated energetic state) through a sequential, coherent excitation process. One excitation process, known as a ladder scheme, uses the probe and coupling lasers to couple three distinct energy states-the probe laser resonantly coupling a first state and a second state, and the coupling laser resonantly coupling the second state and a third (Rydberg) state. In this third (Rydberg) state, the atomic medium becomes more transparent (that is, less absorbing) of the probe laser as a direct result of depopulating the first and second states and populating the third (Rydberg) state. A time-varying electromagnetic field incident at the atomic medium may then cause a time-varying distortion in the energy level structure of the atomic medium. A particular third (Rydberg) state may be selected (by using corresponding frequencies for the probe and coupling lasers) such that, when distortion in the energy level structure occurs by the presence of the electromagnetic field, the coupling laser becomes off-resonance with the transition between the second state and third (Rydberg) state in the distorted energy level structure. This limits the coupling of the second state and third (Rydberg) state so the atomic medium becomes less transparent (that is, more absorbing) of the probe laser.

The electromagnetic field may therefore be detected from this change in transparency as a change in intensity of the probe laser, thus creating a Rydberg-atom based Amplitude Modulated (AM) electromagnetic field detector.

Put another way, the frequencies of the probe and coupling lasers may be selected so as to couple first, second, and third (Rydberg) states, in which an energy difference between the third (Rydberg) state and a fourth (Rydberg) state corresponds with the energy of the electromagnetic field incident at the atomic medium. A more detailed explanation of this effect can be found in the article, “A Multiple-Band Rydberg-Atom Based Receiver/Antenna: AM/FM Stereo Reception”, Holloway et al., National Institute of Standards and Technology).

The Rydberg-atom based electromagnetic field detector can also be used to locate a source of an electromagnetic field. UK Patent Publication No. 2588754—hereby incorporated by reference-discloses an optical fiber array comprising alternating sections of Single Mode Fiber (SMF) and Hollow Core Fiber (HCF), each HCF section comprising an atomic medium excited to a particular Rydberg state and therefore configured to detect an electromagnetic field at a particular frequency. Each HCF segment had a unique combination of separation distances to other HCF segments of the array. As the electromagnetic field passes through each HCF segment of the array, the electromagnetic field causes a change in transparency of the probe signal passing through that HCF segment at that time. As the attenuation of the probe signal due to the electromagnetic field is proportional to the signal strength of the electromagnetic field as it passes through the HCF segment, and the signal strength of the electromagnetic field is inversely proportional to the square of the distance travelled by the electromagnetic field, then the attenuation of the probe signal will be greater for HCF segments that are closer to the source of the electromagnetic field compared to the attenuation of the probe signal for HCF segments that are further away from the source of the electromagnetic field. The probe signal, following its passage of the HCF segments in the array, may be analyzed to determine the location of the source of the electromagnetic field based on the time differences between the changes in transparency of the probe signal and each HCF segment's unique combination of separation distances to other HCF segments of the array.

### SUMMARY

According to a first aspect of the disclosure, there is provided a Rydberg-atom based electromagnetic field detector array comprising a plurality of Rydberg-atom based electromagnetic field detectors, wherein each Rydberg-atom based electromagnetic field detector is divided into a plurality of units, each unit of the plurality of units being either: a variable transparency unit configured to vary its transparency by the Electromagnetically Induced Transparency (EIT) effect and further vary its transparency in response to an incident electromagnetic field, or a separator unit, wherein a sequence of one or more variable transparency units and one or more separator units of the plurality of units for a Rydberg-atom based electromagnetic field detector uniquely identifies that Rydberg-atom based electromagnetic field detector in the Rydberg-atom based electromagnetic field detector array.

According to a second aspect of the disclosure, there is provided an electromagnetic field detector comprising: an optical transmitter; an optical receiver; and a Rydberg-atom based electromagnetic field detector array of the first aspect of the disclosure, wherein: the optical transmitter is configured to: transmit a probe signal to the optical receiver via the Rydberg-atom based electromagnetic field detector array at a probe frequency, and transmit a coupling signal to the optical receiver via the Rydberg-atom based electromagnetic field detector array at a coupling frequency, wherein the probe and coupling frequencies are set to vary the transparency of the probe signal at each variable transparency unit of each Rydberg-atom based electromagnetic field detector of the Rydberg-atom based electromagnetic field detector array by an Electromagnetically Induced Transparency (EIT) effect and so that an electromagnetic field incident at a variable transparency unit of a Rydberg-atom based electromagnetic field detector of the Rydberg-atom based electromagnetic field detector array further varies the transparency of the probe signal at that variable transparency unit so as to cause a detectable change in power of the probe signal at the optical receiver.

According to a third aspect of the disclosure, there is provided a method of operating an electromagnetic field detector, the electromagnetic field detector comprising the Rydberg-atom based electromagnetic field detector array of the first aspect of the disclosure, the method comprising monitoring a probe signal, wherein the probe signal and a coupling signal have been transmitted along the Rydberg-atom based electromagnetic field detector array at a probe frequency and coupling frequency respectively, wherein the probe and coupling frequencies are set to vary the transparency of the probe signal at each variable transparency unit of each Rydberg-atom based electromagnetic field detector of the Rydberg-atom based electromagnetic field detector array by an Electromagnetically Induced Transparency (EIT) effect and so that an electromagnetic field incident at a variable transparency unit of a Rydberg-atom based electromagnetic field detector of the Rydberg-atom based electromagnetic field detector array further varies the transparency of the probe signal at that variable transparency unit so as to cause a detectable change in power of the probe signal at the optical receiver; detecting an attenuation event as a sequence of one or more probe signal portions at a first power level and one or more probe signal portions at a second power level; and identifying a Rydberg-atom based electromagnetic field detector of the Rydberg-atom based electromagnetic field detector array by correlating the sequence of one or more probe signal portions at a first power level and one or more probe signal portions at a second power level of the detected attenuation event with the unique sequence of one or more variable transparency units and one or more separator units of the plurality of units for the Rydberg-atom based electromagnetic field detector.

The method may further comprise identifying a plurality of Rydberg-atom based electromagnetic field detectors of Rydberg-atom based electromagnetic field detector array, wherein at least one of the plurality of Rydberg-atom based electromagnetic field detectors is identified by correlating the sequence of one or more probe signal portions at a first power level and one or more probe signal portions at a second power level of the detected attenuation event with the unique sequence of one or more variable transparency units and one or more separator units of the plurality of units for the Rydberg-atom based electromagnetic field detector; and determining a location of the transmitter of the electromagnetic field based on the identified plurality of Rydberg-atom based electromagnetic field detectors.

The method may further comprise determining a distance between each of the identified plurality of Rydberg-atom based electromagnetic field detectors and a transmitter of the electromagnetic field, wherein the location of the transmitter of the electromagnetic field is based on the determined distances between each of the identified plurality of Rydberg-atom based electromagnetic field detectors and the transmitter of the electromagnetic field. Determining the location of the transmitter may be based on a machine-learning technique.

According to a fourth aspect of the disclosure, there is provided a computer program comprising instructions which, when the program is executed by the electromagnetic field detector of the second aspect of the disclosure, cause the electromagnetic field detector to carry out the method of the third aspect of the disclosure. The computer program may be stored on a computer readable carrier medium.

A first subset of variable transparency units of the plurality of units of a Rydberg-atom based electromagnetic field detector of the plurality of Rydberg-atom based electromagnetic field detectors may be configured to further vary its transparency in response to the incident electromagnetic field by a first magnitude and a second subset of variable transparency units of the plurality of units of the Rydberg-atom based electromagnetic field detector of the plurality of Rydberg-atom based electromagnetic field detectors may be configured to further vary its transparency in response to the incident electromagnetic field by a second magnitude.

The variable transparency unit may comprise a metal vapor, the metal vapor may be of an alkali metal, and the alkali metal vapor may be one of: Rubidium, Cesium or Strontium.

The electromagnetic field may be a Radio Frequency (RF) field.

### BRIEF DESCRIPTION OF THE FIGURES

In order that the present disclosure may be better understood, embodiments thereof will now be described, by way of example only, with reference to the accompanying drawings in which:

FIG. 1 is a schematic diagram of a cellular telecommunications network.

FIG. 2 is a schematic diagram of a Rydberg-atom based Radio Frequency (RF) detector array.

FIG. 3 is a schematic diagram of the Rydberg-atom based RF detector array, an optical equipment housing and a User Equipment (UE).

FIG. 4 is a flow diagram illustrating a method.

FIGS. 5a to 5c are schematic diagrams illustrating an RF pulse affecting three Rydberg-atom based RF detectors of the Rydberg-atom based RF detector array at first, second and third time instances, respectively.

FIG. 5d is a graph illustrating the ratio of the received power to the transmitted power of a probe signal of the Rydberg-atom based RF detector array as affected in the scenario of FIGS. 5a to 5c.

FIG. 6 is a graph illustrating the ratio of the received power to the transmitted power of a probe signal of the Rydberg-atom based RF detector array.

FIG. 7 is a flow diagram illustrating a method.

### DETAILED DESCRIPTION

In wireless telecommunications, a wireless signal is transmitted at a particular power level and its signal strength decreases with distance from the transmitter based on the path loss of the transmission environment. The wireless signal cannot be detected once its signal strength is no longer detectable above a background noise level at a detector. The signal strength of the wireless signal at the detector is affected by further factors such as multi-path propagation (due to reflection and refraction), dispersion, Doppler shadowing and variable shadowing. Accordingly, the wireless signal has a maximum range defined by its transmit power, the channel gain (being a function of the path loss and the further factors) and the background noise level.

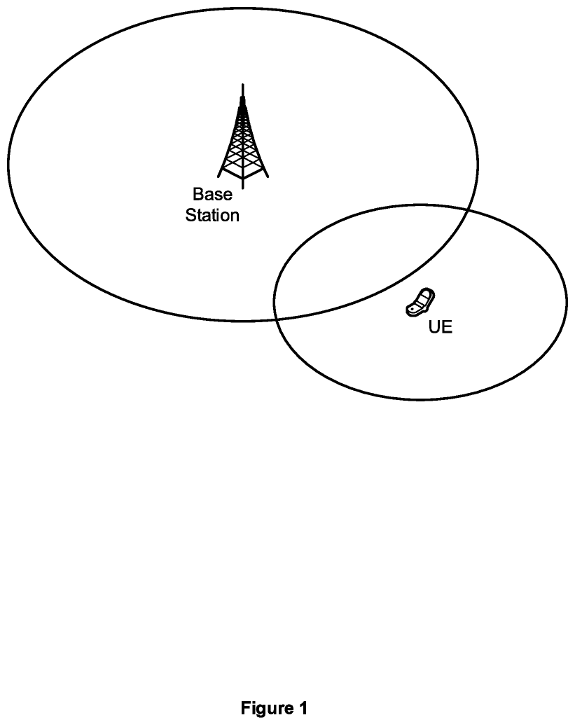

In cellular telecommunications networks, wireless signals are transmitted between base stations and User Equipment (UE). An example cellular telecommunications network is shown in FIG. 1, illustrating a base station and a UE and their respective coverage areas. In this scenario, the UE cannot receive wireless signals from the base station and, in the absence of alternatives, cannot receive voice or data service. Furthermore, as the base station is outside the UE's coverage area, it cannot receive wireless signals from the UE. The skilled person will understand that this problem is experienced in other forms of wireless telecommunications, such as in Wireless Local Area Networks (WLANs), where two devices of the network cannot communicate as they are located outside the other device's respective coverage area.

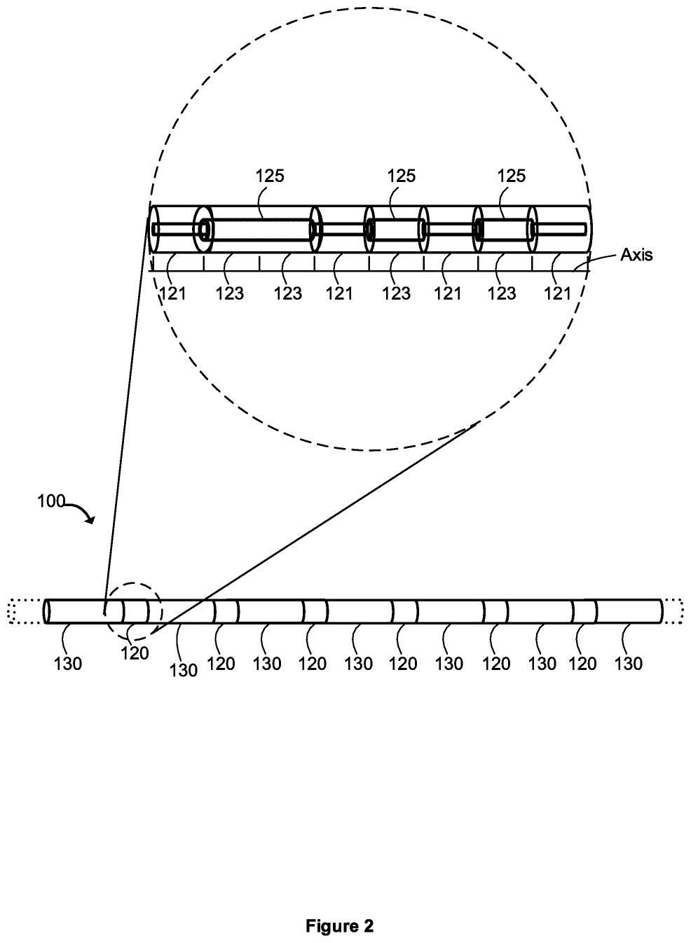

FIG. 2 illustrates a Rydberg-atom based Radio Frequency (RF) detector array 100. The Rydberg-atom based RF detector array 100 includes an optical fiber having a plurality of Rydberg-atom based RF detectors 120 positioned on the optical fiber. Each Rydberg-atom based RF detector 120 is separated from its one or more neighbouring Rydberg-atom based RF detectors 120 on the optical fiber by a Single-Mode-Fiber (SMF) segment 130.

FIG. 2 also highlights a particular Rydberg-atom based RF detector 120 of the array 100. The Rydberg-atom based RF detector 120 comprises a plurality of units (indicated by the tick marks on the axis), each having the same predetermined length and being either an SMF unit 121 or a Hollow Core Fiber (HCF) unit 123. The Rydberg-atom based RF detector 120 may include contiguous units of the same type—as illustrated in FIG. 2 in which the second and third units (from the left) of the highlighted Rydberg-atom based RF detector 120 are both HCF units. Each HCF unit 123 includes an optical cavity 125 containing a vapor of alkali metal (in this example, Rubidium-85). The sequence of one or more HCF units and one or more SMF units in each Rydberg-atom based RF detector 120 is unique to that Rydberg-atom based RF detector 120 in the Rydberg-atom based RF detector array 100. As discussed below, this sequence acts as a barcode to enable identification of the particular Rydberg-atom based RF detector 120 associated with an attenuation event in a probe signal that has passed through the Rydberg-atom based RF detector array 100.

The plurality of units comprises eight units in FIG. 2, but this is merely an example.

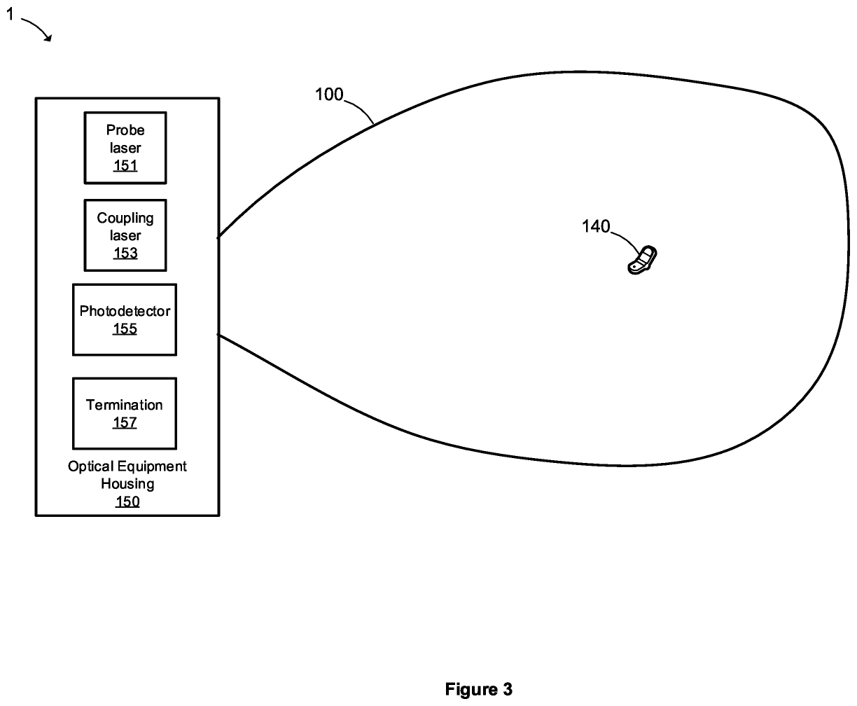

FIG. 3 illustrates a first use case of the Rydberg-atom based RF detector array 100 as a geolocator of a source of a wireless signal in a wireless telecommunications network 1. FIG. 3 illustrates an optical equipment housing 150 and the Rydberg-atom based RF detector array 100 originating and terminating at the optical equipment housing 150. The position of each Rydberg-atom based RF detector 120 of the array 100 is known. These positions may be determined, for example, during a calibration phase in which the Global Navigation Satellite System (GNSS) coordinates are obtained at the position of each Rydberg-atom based RF detector 120.

FIG. 3 also illustrates a User Equipment (UE) 140 as a source of a wireless signal having a particular frequency. In this example, the UE 140 is encircled by the Rydberg-atom based RF detector array 100.

The optical equipment housing 150 includes a probe laser 151, a coupling laser 153, a photodetector 155 and a non-reflecting termination 157. The probe laser 151 transmits a probe signal along the Rydberg-atom based RF detector array 100 in a first direction (e.g. clockwise) and the coupling laser 153 transmits a coupling signal along the Rydberg-atom based RF detector array 100 in a second direction (e.g. counter-clockwise) counter-propagating and overlapping the probe signal. The probe signal, following its passage of the Rydberg-atom based RF detector array 100, is directed towards the photodetector 155. The coupling signal, following its passage of the Rydberg-atom based RF detector array 100, is directed towards the non-reflecting termination 157.

In this embodiment, the probe signal is on-resonance with the transition of an electron of a Rubidium-85 atom within each optical cavity of each HCF unit of each Rydberg-atom based RF detector 120 of the Rydberg-atom based RF detector array 100 from a ground state to a first excited state. Furthermore, the coupling signal is on-resonance with the transition of an electron of a Rubidium-85 atom within each optical cavity of each HCF unit of each Rydberg-atom based RF detector 120 of the Rydberg-atom based RF detector array 100 from the first excited state to a predetermined Rydberg state. In this configuration, each HCF unit of each Rydberg atom based RF detector 120 experiences the EIT effect and the Rydberg-atom based RF detector array 100 is more transparent to the probe signal (and may be sufficiently low loss to be considered near transparent). The skilled person will understand that to achieve the EIT effect along the whole length of the Rydberg-atom based RF detector array 100 then the density of the vapor in the HCF units, the number of HCF units, and the power of the coupling laser must be selected so that the EIT effect is experienced in all HCF units. That is, the coupling signal will be partially attenuated by each HCF unit in each Rydberg-atom based RF detector 120, so the coupling laser must transmit at a power so that (for a given number of HCF units and given density of vapor in the HCF units), the coupling signal is of sufficient power to elevate the electrons in the final HCF unit to the predetermined Rydberg state, thus depopulating the ground state in the final HCF unit and causing the final HCF unit to be more transparent to the probe signal.

The predetermined Rydberg state is selected based on the specific frequencies of the probe and coupling signals so that a wireless signal from the UE 140, incident upon one or more HCF units 123, has a frequency corresponding with the energy difference between the predetermined Rydberg state and another Rydberg state, such that a change in the probe signal is detectable at the photodetector 155. In this example, in which the UE 140 transmits wireless signals at around 3.58891 GHZ, the probe frequency is 780.2463 nm and the coupling frequency is 479.4370 nm so that electrons are excited to the 84th Rydberg state.

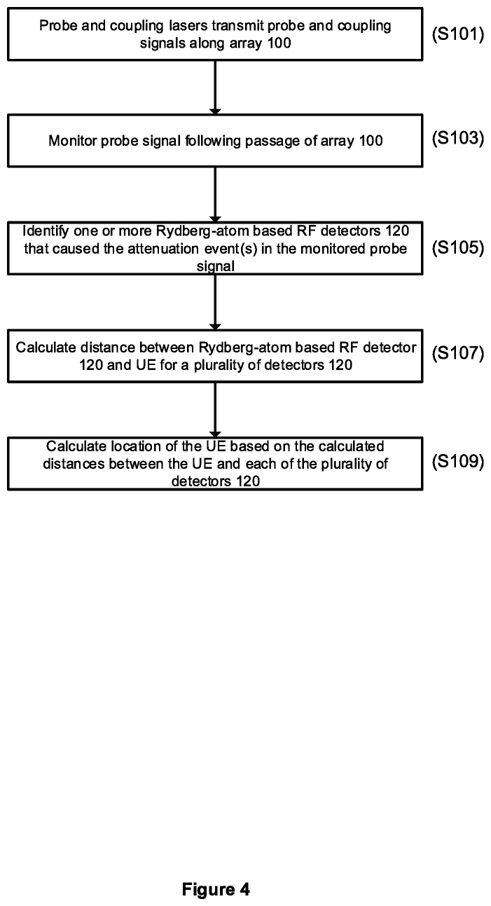

FIG. 4 is a flow-diagram illustrating a first method. In S101 of this first method, the probe and coupling lasers 151, 153 respectively transmit probe and coupling signals along the Rydberg-atom based RF detector array 100 so as to excite each HCF unit of each Rydberg-atom based RF detector 120 to the predetermined Rydberg state. In the absence of an incident RF field at the frequency to be detected, then the probe signal will pass through the Rydberg-atom based RF detector array 100 with minimal attenuation (as all HCF units in the Rydberg-atom based RF detector array 100 are more transparent to the probe signal in the absence of the incident RF field) and is received at the photodetector 155. As the travel time of the probe signal is known to a very high accuracy, the received signal and transmitted signal can be compared to determine the attenuation at each point of the probe signal. Assuming negligible transmission losses, the attenuation at each point of the probe signal is 0 dB such that the ratio of the received power to transmitted power of the probe signal is 100%.

In this example, the UE 140 emits an RF field in a single pulse (hereinafter, the “RF pulse”). This RF pulse will therefore pass through each HCF unit of each Rydberg-atom based RF detector 120 of the Rydberg-atom based RF detector array 100 and (as explained above) will cause a change in transparency of the probe signal passing through that HCF unit at that time. As the attenuation of the probe signal due to the RF pulse is proportional to the signal strength of the RF pulse as it passes through the HCF unit, and the signal strength of the RF pulse is a function of the channel gain, then the attenuation of the probe signal will generally be greater for HCF units that are closer to the UE 140 compared to the attenuation of the probe signal for HCF units that are further away from the UE 140.

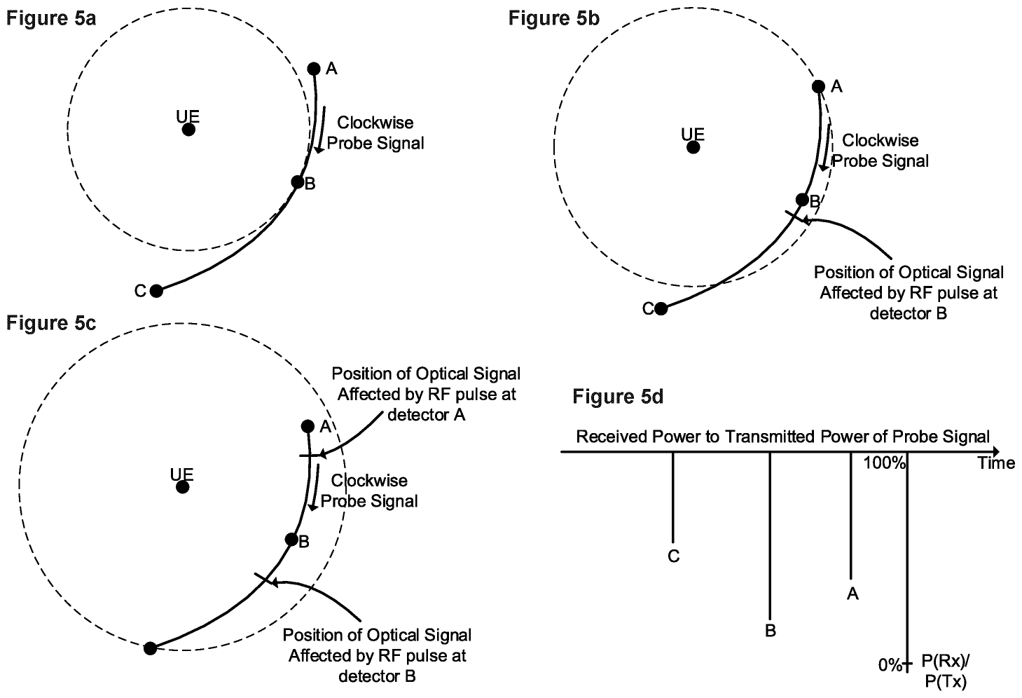

To illustrate these attenuations in more detail, FIGS. 5a to 5c illustrate a selection of three Rydberg-atom based RF detectors (labelled A, B and C) of the Rydberg-atom based RF detector array 100 and the UE 140 at first, second and third time instances following transmission of an RF pulse from the UE 140. FIG. 5d is a graph illustrating the ratio of the received power to the transmitted power of the probe signal as received at the photodetector 155. The distance between the UE 140 and the Rydberg-atom based RF detector B is less than the distance between the UE 140 and Rydberg-atom based RF detector 120 A, which is in turn less than the distance between the UE 140 and Rydberg-atom based RF detector C. Furthermore, the distance between Rydberg-atom based RF detectors B and C is greater than the distance between Rydberg-atom based RF detectors A and B.

FIG. 5a illustrates the RF pulse at a first time instance (as illustrated by a dotted-line circle centered around the UE 140) in which the RF pulse is passing through the closest Rydberg-atom based RF detector, B, but has not yet reached Rydberg-atom based RF detectors A and C. The RF pulse passes through Rydberg-atom based RF detector B and, during its passage, causes an attenuation of the strength of the probe signal passing through Rydberg-atom based RF detector B at that time. FIG. 5b illustrates the RF pulse at a second time instance, subsequent to the first time instance, in which the RF pulse has propagated further from the UE 140 such that it is beyond Rydberg-atom based RF detector B, is passing through Rydberg-atom based RF detector A but has not yet reached Rydberg-atom based RF detector C. The RF pulse passes through Rydberg-atom based RF detector A and, during its passage, causes an attenuation of the strength of the probe signal passing through Rydberg-atom based RF detector A at that time. FIG. 5c illustrates the RF pulse at a third time instance, subsequent to the second time instance, in which the RF pulse has propagated further from the UE 140 such that it is beyond Rydberg-atom based RF detectors A and B and is now passing through Rydberg-atom based RF detector C. The RF pulse passes through Rydberg-atom based RF detector C and, during its passage, causes an attenuation of the strength of the probe signal passing through Rydberg-atom based RF detector C at that time. As the RF pulse is weaker during its passage of Rydberg-atom based RF detector C than during its passage of Rydberg-atom based RF detector A, and is weaker during its passage of Rydberg-atom based RF detector A than during its passage of Rydberg-atom based RF detector B (due to the relative distances and constant path loss), then the attenuation of the probe signal passing through Rydberg-atom based RF detector B during the passage of the RF pulse is greater than the attenuation of the probe signal passing through Rydberg-atom based RF detector A during the passage of the RF pulse, which is in turn greater than the attenuation of the probe signal passing through Rydberg-atom based RF detector C during the passage of the RF pulse. FIG. 5d illustrates the monitored signal at the photodetector 155, which illustrates the ratio of the received probe signal to the transmitted signal, so as to indicate the strength of the attenuation of the probe signal against time. The first attenuation received at the photodetector 155 is that of Rydberg-atom based RF detector C (which is closest to the photodetector 155), the second attenuation received at the photodetector 155 is that of Rydberg-atom based RF detector B, and the third attenuation received at the photodetector 155 is that of Rydberg-atom based RF detector A. It is noted that the separation in time between these attenuations is a combination of both the time difference between the RF pulse arriving at the respective Rydberg-atom based RF detectors and the time difference for the probe signal to traverse the Rydberg-atom based RF detector array 100 between the respective Rydberg-atom based RF detectors. Furthermore, it is noted that the time difference between the RF pulse arriving at the respective Rydberg-atom based RF detectors causes the attenuations to be either further apart or closer together than they would appear if the RF pulse passed through the Rydberg-atom based RF detectors at the same time depending on whether the Rydberg-atom based RF detector that is subsequently affected by the RF pulse is closer to or further away from the photodetector than the Rydberg-atom based RF detector that was previously affected by the RF pulse.

In this example, the attenuation of the probe signal for Rydberg-atom based RF detector A appears further away from the attenuation of the probe signal for Rydberg-atom based RF detector B as Rydberg-atom based RF detector A is further away from the photodetector 155 (and so the probe signal moves towards the photodetector 155, and away from Rydberg-atom based RF detector A, in the time period between the first and second time instances), and the attenuation of the probe signal for Rydberg-atom based RF detector C appears closer to the attenuation of the probe signal for Rydberg-atom based RF detector B as Rydberg-atom based RF detector C is closer to the photodetector 155 (and so the probe signal moves towards the photodetector 155, and towards Rydberg-atom based RF detector C, in the time period between the first and third time instances).

On the scale of the Rydberg-atom based RF detector array 100 in which different Rydberg-atom based RF detectors 120 may have different respective distances to the source of the RF pulse, then the attenuation experienced by each HCF unit of a particular Rydberg-atom based RF receiver 120 may be different to the attenuation experienced by each HCF unit of a different Rydberg-atom based RF receiver 120. Furthermore, as discussed above, these attenuations may be shifted (that is, as described above in relation to FIG. 5, appear closer together or further apart than they would appear if the RF pulse passed through the Rydberg-atom based RF detectors at the same time).

As the size of each Rydberg-atom based RF detector 120 in the array 100 is significantly less than the distance travelled by the RF pulse, then it can be assumed that the signal strength experienced by each HCF unit of a particular Rydberg-atom based RF detector 120 is equal (such that the attenuations caused by the RF pulse at each HCF unit of that Rydberg-atom based RF detector 120 are the same). Nonetheless, there may still be a shifting of attenuations (as described above in relation to FIG. 5) for different HCF units of a Rydberg-atom based RF detector 120. This shifting should not be on the same scale as the predetermined length of the HCF units 123 and SMF units 121 (e.g. equal to or greater than half the predetermined length), which effectively sets a minimum length for the HCF units 123 and SMF units 121 of the Rydberg-atom based RF detector 120.

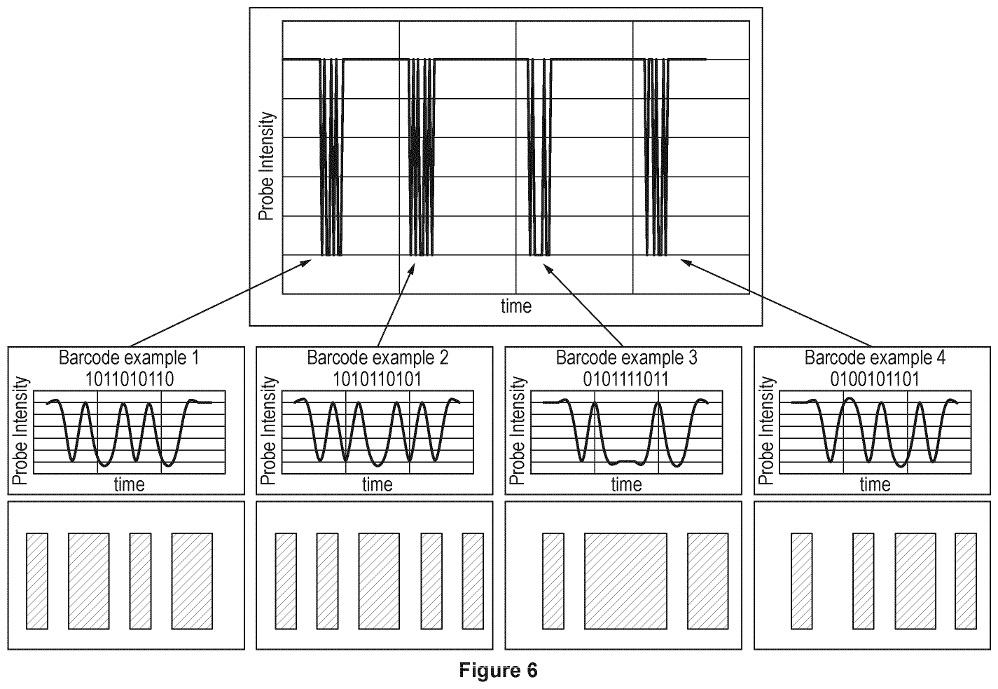

In S103, the photodetector 155 monitors the probe signal following its passage of the Rydberg-atom based RF detector array 100. An example of a monitored probe signal is shown in FIG. 6, which illustrates an attenuation event for each Rydberg-atom based RF detector 120 of the array 100. Each attenuation event is a sequence of attenuations caused by the HCF units of a particular Rydberg-atom based RF detector 120. The attenuations of the sequence of attenuations are closely spaced relative to the spacing between adjacent attenuation events, owing to the small distances between HCF units relative to the large distances between Rydberg-atom based RF detectors 120.

In S105, the identity of the Rydberg-atom based RF detector 120 that caused each attenuation event in the monitored probe signal is determined. As noted above, the plurality of units of each Rydberg-atom based RF detector 120 are of a fixed predetermined length, which corresponds with a fixed time duration in the monitored probe signal. Accordingly, each HCF unit of the Rydberg-atom based RF detector 120 corresponds with an attenuation in the monitored probe signal for the fixed time duration (and a number of contiguous HCF units of the Rydberg-atom based RF detector 120 correspond with an attenuation in the monitored probe signal for a time period equal to the number of HCF units multiplied by that fixed time duration), and each SMF unit of the Rydberg-atom based RF detector 120 corresponds with the monitored probe signal being at a reference level for the fixed time duration (and a number of contiguous SMF units of the Rydberg-atom based RF detector 120 correspond with the monitored probe signal being at the reference level for a time period equal to the number of SMF units multiplied by that fixed time duration).

The identity of the Rydberg-atom based RF detector 120 that causes each attenuation event may therefore be determined by identifying each portion of the monitored probe signal at a first power level for the fixed time duration as an HCF unit and each portion of the monitored probe signal at a second power level (that is, the reference power level) for the fixed time duration as an SMF unit. The sequence of one or more probe signal portions at the first power level and one or more probe signal portions at the reference power level in the attenuation event corresponds with the sequence of one or more HCF units and one or more SMF units in the Rydberg-atom based RF detector 120. As this sequence is unique, then the photodetector 155 may identify the Rydberg-atom based RF detector 120 by matching the determined sequence of one or more probe signal portions at the first power level and one or more probe signal portions at the second power level in the attenuation event with a reference table (stored locally at the photodetector 155 or accessible via a communications interface) storing the unique sequences of one or more HCF units and one or more SMF units in each Rydberg-atom based RF detector 120.

The unique sequence of HCF units and SMF units of all Rydberg-atom based RF detectors 120 in the array may include a particular sub-sequence. This enables the photodetector 155 to distinguish between adjacent Rydberg-atom based RF detectors 120 based on the presence of the sub-sequence in a sequence of HCF units and SMF units following a time period corresponding to the minimum distance between adjacent Rydberg-atom based RF detectors 120 on the array 100. This sub-sequence may be placed at a particular relative position of the sequence, such as the start of the sequence. The sub-sequence may be, for example, a single HCF unit.

The reference table may also indicate the relative positions of each Rydberg-atom based RF detector 120 in the array 100, such that it only necessary for a single Rydberg-atom based RF detector 120 to be identified as the cause of a particular attenuation event by the process outlined above and the identities of the Rydberg-atom based RF detector 120 that caused each other attenuation event may be inferred by the relative positions.

In S107, the distance between a Rydberg-atom based RF detector 120 and the UE 140 is calculated for a plurality of Rydberg-atom based RF detectors 120 as:

$${D}_{N} = \frac{3 * ( {AT}_{M} - {AT}_{N} - {T}_{M , N} )}{10 * \sqrt{{A}_{N}} * ( \frac{1}{\sqrt{{A}_{M}}} - \frac{1}{\sqrt{{A}_{N}}} )}$$

in which,
D_{N} is the distance between a Rydberg-atom based RF detector 120, N, and the UE 140,
AT_{N} is the time an RF pulse (transmitted by the UE 140) attenuates a first Rydberg-atom based RF detector 120 N,
AT_{M} is the time the RF pulse attenuates a second Rydberg-atom based RF detector 120 M,
T_{M,N} is the time difference for an optical pulse to travel between the first Rydberg-atom based RF detector 120, N, and the second Rydberg-atom based RF detector 120, M,
A_{M} is the magnitude of the attenuation event associated with the second Rydberg-atom based RF detector 120, M, and
A_{N} is the magnitude of the attenuation event associated with the first Rydberg-atom based RF detector 120, N.

The above equation is derived from the following analysis. It is known that the RF pulse travels between the UE 140 and the first Rydberg-atom based RF detector 120, N, at the speed of light in free space:

$$c = \frac{{D}_{N}}{{RFT}_{N}} \approx 0.3 m / ns \qquad ( 1 )$$

Where RFT_{N} is the arrival time of the RF pulse at the first Rydberg-atom based RF detector 120, N.

It is also assumed that there is a constant path loss for the RF pulse between the UE 140 and the first Rydberg-atom based RF detector 120, N:

$${A}_{N} = \frac{P}{{D}_{N}^{2}} \qquad ( 2 )$$

Where P is a constant and assumed to be equal among all Rydberg-atom based RF detectors 120.

The time difference between the reception time of an attenuation event at the second Rydberg-atom based RF detector 120 M and the reception time of an attenuation event at the first Rydberg-atom based RF detector 120 N can be expressed as:

$${AT}_{M} - {AT}_{N} = {T}_{M , N} + {RFT}_{M} - {RFT}_{N} \qquad ( 3 )$$

Rearranging equations (1) to (3), and assuming constant P is constant among all HCF segments, then the following solutions may be derived:

$$P = {( \frac{3 * ( {AT}_{M} - {AT}_{N} - {T}_{M , N} )}{10 * ( \frac{1}{\sqrt{{A}_{M}}} - \frac{1}{\sqrt{{A}_{N}}} )} )}^{2}$$

$${D}_{N} = \frac{3 * ( {AT}_{M} - {AT}_{N} - {T}_{M , N} )}{10 * \sqrt{{A}_{N}} * ( \frac{1}{\sqrt{{A}_{M}}} - \frac{1}{\sqrt{{A}_{N}}} )}$$

$${RFT}_{N} = \frac{{AT}_{M} - {AT}_{N} - {T}_{M , N}}{\sqrt{{A}_{N}} * ( \frac{1}{\sqrt{{A}_{M}}} - \frac{1}{\sqrt{{A}_{N}}} )}$$

In S109, the location of the UE 140 is determined based on the distances between the UE 140 and several Rydberg-atom based RF detectors 120, and the locations of each of those Rydberg-atom based RF detectors, using known multilateration techniques.

The Rydberg-atom based RF detector array 100 and method described above is an improved method of geolocating the wireless signal source. The Rydberg-atom based RF detector of UK patent publication number 2588754 requires each HCF unit to have particular separation distances to other HCF units of the detector. In contrast, the position of each Rydberg-atom based RF detector 120 on the Rydberg-atom based RF detector array 100 is independent of the position of any other Rydberg-atom based RF detector 120 on the array 100. This independence improves the flexibility of the device such that an increased density of Rydberg-atom based RF detectors 120 may be achieved by using relatively short distances between a first subset of Rydberg-atom based RF detectors on one part of the array 100 relative to the distances between a second subset of Rydberg-atom based RF detectors on another part of the array 100. As each Rydberg-atom based RF detector 120 may also operate as a receiver (in which the RF signal received at the Rydberg-atom based RF detector 120 is demodulated), then this increased density of Rydberg-atom based RF detectors 120 may be used in areas of increased demand for uplink capacity in a wireless network. Furthermore, this independence allows further Rydberg-atom based RF detectors 120 to be added to the array 100 subsequent to the array's deployment.

The density of the Rydberg-atom based RF detectors 120 may also be increased by deploying the array 100 such that a first subset of Rydberg-atom based RF detectors 120 in one part of the array 100 are spaced close to each other relative to a second subset of detectors 120 of the array 100, such as by coiling or zig-zagging the part of the array 100 containing the first subset of Rydberg-atom based RF detectors 120.

In the above embodiment, the distance between a Rydberg-atom based RF detector 120 and the UE 140 is calculated for a plurality of Rydberg-atom based RF detectors 120, using the function noted in S107 above, and the location of the UE 140 is then determined using a multilateration technique in S109. However, the skilled person will understand that other methods of geolocating the UE 140 based on the monitored probe signal are possible. For example, a machine-learning approach could be used. The machine-learning approach may implement a training phase to determine a geolocation function. The training phase may be based on training data in which a set of input parameters-including one or more of the monitored probe signal, the identity of the Rydberg-atom based RF detector 120 that caused each attenuation event in the monitored probe signal, and the location (e.g. GNSS coordinates) of each Rydberg-atom based RF detector 120—are mapped to an output parameter—the location of the UE 140—by supervised learning. The training data may be obtained by transmitting an RF pulse from the UE 140 from multiple locations and recording each location (e.g. its GNSS coordinates) and its corresponding monitored probe signal. As noted above, the location of each Rydberg-atom based RF detector 120 may be recorded when the array 100 is deployed. The known locations of the UE 140 may relate to known paths (e.g. series of locations) of the UE 140, and their corresponding series of monitored probe signals.

Once the geolocation function has been determined following the training phase (and optionally a validation phase using validation data), then it may be used to determine the location of a source of an RF pulse following identification of the Rydberg-atom based RF detector 120 that caused each attenuation event in a monitored probe signal (in S105 above). A re-training phase may be implemented (e.g. periodically or in response to a known change in the propagation environment) to update the geolocation function.

S107 and S109 outlined above are particularly suitable for geolocating the UE 140 when attenuation of the signal strength of the RF pulse is caused primarily due to path loss relative to the further factors noted above, such as multi-path propagation (due to reflection and refraction), dispersion, Doppler shadowing and variable shadowing. The machine learning approach discussed above is suitable for geolocating the UE 140 regardless of the cause of signal strength attenuation.

The skilled person will understand that the unique sequence of HCF units and SMF units for each Rydberg-atom based RF detector 120 may be implemented with any number of units, so long as the number of unique combinations is equal to or greater than the number of Rydberg-atom based RF detectors 120 in the array 100.

In the above embodiment, the HCF segments contain an atomic medium based on Rubidium-85 which may experience the EIT effect and have Rydberg states having energy differences that correlate with the photonic energy of frequencies used in wireless telecommunication protocols. The RF detector may therefore be configured to detect RF waves of a particular frequency by setting the probe and coupling frequencies to excite electrons to a particular Rydberg state, wherein the energy difference between that Rydberg state and the next Rydberg state matches the photonic energy of the RF wave to be detected. The skilled person will therefore understand that the use of Rubidium-85 is non-essential, and any atomic medium that may react to an RF wave so as to vary its transparency to the probe signal may be used in the above embodiment. The RF detector therefore does not need to be an end-to-end optical fiber, but may be any device with interleaved separator sections and Rydberg-atom based RF detector sections. Furthermore, it is also non-essential that the sections of optical fiber between the Rydberg-atom based RF detector sections are made of SMF. For example, multi-mode fiber may be used instead. In another example, the segments between Rydberg-atom based RF detectors are also constructed of HCF, but with a different concentration of Rubidium to ensure that the attenuation events caused by the HCF units of the Rydberg-atom based RF detectors can be distinguished in the probe signal.

Furthermore, it is non-essential that each Rydberg-atom based RF detector 120 includes a particular sub-sequence such that the attenuation events caused by the Rydberg-atom based RF detectors 120 are distinguishable in the probe signal. As noted above, the segments between Rydberg-atom based RF detectors 120 could be constructed of HCF and configured such that its response to an incident RF field is distinguishable from the responses of the HCF units and SMF units of the Rydberg-atom based RF detectors 120. The photodetector 155 may therefore identify the start of each sequence of HCF units and SMF units in each Rydberg-atom based RF detector 120 by the change in response relative to the response to the HCF of the segments between Rydberg-atom based RF detectors 120.

It is also non-essential that the detector is configured to detect electromagnetic fields in the RF band of the electromagnetic spectrum. That is, the detector may be configured so that the variable transparency section varies it transparency in response to incident electromagnetic fields of other parts of the spectrum (e.g. by using an atomic medium with particular energy states and by selecting appropriate probe and coupling frequencies, as described above). The method of the above embodiment may therefore be used as an electromagnetic field detector. It is also non-essential that the EIT effect is experienced by using a ladder excitation scheme, as described above. Other schemes, such as lambda or Vee may be used instead.

Furthermore, it is non-essential for the probe and coupling signals to be counter-propagating. However, this is preferable as the Doppler shift effect may be ignored.

The Rydberg-atom based RF detector array 100 described above produces a binary response at the photodetector 155, in which each HCF unit corresponded with the probe signal at a first power level and each SMF unit corresponded with the probe signal at a reference power level. In a further implementation, the HCF units may be designed to cause different attenuations in the probe signal such that a first subset of HCF units of a Rydberg-atom based RF detector correspond with the probe signal at a first power level, a second subset of HCF units of the Rydberg-atom based RF detector correspond with the probe signal at a second power level. This may be achieved by using different concentrations of Rubidium in the HCF units. The sequence of one or more SMF units (corresponding with the probe signal at the reference power level), one or more HCF units of the first subset of HCF units (corresponding with the probe signal at a first power level) and one or more HCF units of the second subset of the HCF units (corresponding with the probe signal at a second power level), may then be used to uniquely identify the Rydberg-atom based RF detector. This further implementation increases the number of unique combinations of sequences available to identify the Rydberg-atom based RF detectors by operating as a 2-dimensional barcode.

The method described above illustrates a first use case of the Rydberg-atom based RF detector array 100 for geolocating an RF field source. However, the skilled person will understand that the Rydberg-atom based RF detector array 100 may be used to identify the Rydberg-atom based RF detector 120 of the array 100 that detected an RF field.

The Rydberg-atom based RF detector array 100 has an additional benefit in that the orientation of each Rydberg-atom based RF detector 120 is a non-essential configuration. That is, as each HCF unit 123 of each Rydberg-atom based RF detector 120 is relatively short, its orientation relative to the incident RF pulse has an insignificant effect on the attenuation of each HCF unit 123. Nonetheless, the orientation of each Rydberg-atom based RF detector 120 may also be used as an input parameter of the training data used in the machine learning approach above. This orientation parameter may enable the geolocation function determined during the training phase to both geolocate the UE 140 and determine an angle of arrival of the RF pulse at each Rydberg-atom based RF detector 120. The training data may therefore further include—as input data-the orientation of each Rydberg-atom based RF detector 120 (obtained during deployment or in-use by a suitable orientation sensor) and—as output data—the angle of arrival of the RF pulse at each Rydberg-atom based RF detector 120 (calculated from the location of the UE 140 and the location of each Rydberg-atom based RF detector 120).

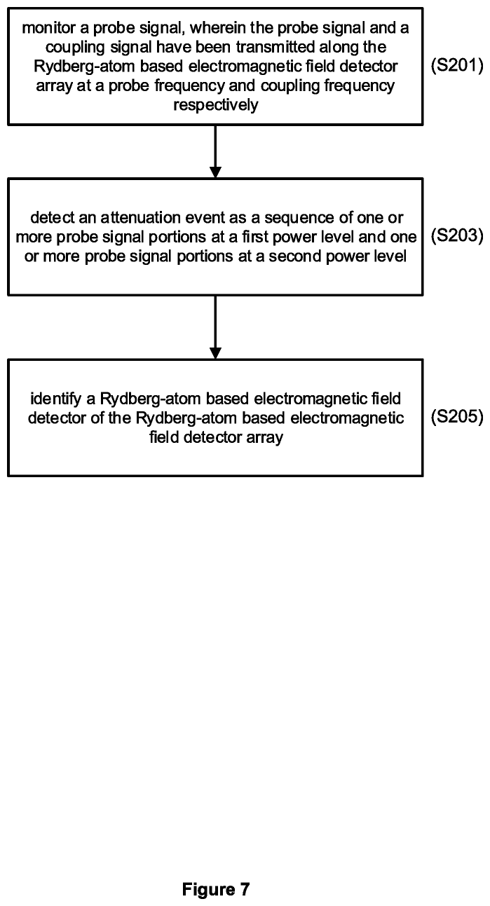

FIG. 7 illustrates a method comprising, at S201, monitoring a probe signal, wherein the probe signal and a coupling signal have been transmitted along the Rydberg-atom based electromagnetic field detector array at a probe frequency and coupling frequency respectively, wherein the probe and coupling frequencies are set to vary the transparency of the probe signal at each variable transparency unit of each Rydberg-atom based electromagnetic field detector of the Rydberg-atom based electromagnetic field detector array by an Electromagnetically Induced Transparency, EIT, effect and so that an electromagnetic field incident at a variable transparency unit of a Rydberg-atom based electromagnetic field detector of the Rydberg-atom based electromagnetic field detector array further varies the transparency of the probe signal at that variable transparency unit so as to cause a detectable change in power of the probe signal at the optical receiver; at S203 detecting an attenuation event as a sequence of one or more probe signal portions at a first power level and one or more probe signal portions at a second power level; and at S205 identifying a Rydberg-atom based electromagnetic field detector of the Rydberg-atom based electromagnetic field detector array by correlating the sequence of one or more probe signal portions at a first power level and one or more probe signal portions at a second power level of the detected attenuation event with the unique sequence of one or more variable transparency units and one or more separator units of the plurality of units for the Rydberg-atom based electromagnetic field detector.

The skilled person will understand that any combination of features is possible within the scope of the disclosure, as claimed.

1. A Rydberg-atom based electromagnetic field detector array comprising:
a plurality of Rydberg-atom based electromagnetic field detectors, wherein each Rydberg-atom based electromagnetic field detector is divided into a plurality of units, each unit of the plurality of units being either:
a variable transparency unit configured to vary a transparency by the Electromagnetically Induced Transparency effect and further vary the transparency in response to an incident electromagnetic field, or
a separator unit,
wherein a sequence of one or more variable transparency units and one or more separator units of the plurality of units for a Rydberg-atom based electromagnetic field detector uniquely identifies that Rydberg-atom based electromagnetic field detector in the Rydberg-atom based electromagnetic field detector array.

2. The Rydberg-atom based electromagnetic field detector array as claimed in claim 1, wherein a first subset of variable transparency units of the plurality of units of a Rydberg-atom based electromagnetic field detector of the plurality of Rydberg-atom based electromagnetic field detectors is configured to further vary the transparency in response to the incident electromagnetic field by a first magnitude and a second subset of variable transparency units of the plurality of units of the Rydberg-atom based electromagnetic field detector of the plurality of Rydberg-atom based electromagnetic field detectors is configured to further vary the transparency in response to the incident electromagnetic field by a second magnitude.

3. The Rydberg-atom based electromagnetic field detector array as claimed in either claim 1, wherein the variable transparency unit comprises a metal vapor.

4. The Rydberg-atom based electromagnetic field detector as claimed in claim 3, wherein the metal vapor is of an alkali metal.

5. The Rydberg-atom based electromagnetic field detector as claimed in claim 4, wherein the alkali metal vapor is one of: Rubidium, Cesium or Strontium.

6. The Rydberg-atom based electromagnetic field detector as claimed in claim 1, wherein the electromagnetic field is a Radio Frequency field.

7. An electromagnetic field detector comprising:
an optical transmitter;
an optical receiver; and
the Rydberg-atom based electromagnetic field detector array as claimed in claim 1, wherein the optical transmitter is configured to:
transmit a probe signal to the optical receiver via the Rydberg-atom based electromagnetic field detector array at a probe frequency, and
transmit a coupling signal to the optical receiver via the Rydberg-atom based electromagnetic field detector array at a coupling frequency,
wherein the probe frequency and the coupling frequency are set to vary the transparency of the probe signal at each variable transparency unit of each Rydberg-atom based electromagnetic field detector of the Rydberg-atom based electromagnetic field detector array by the EIT effect and so that an electromagnetic field incident at a variable transparency unit of a Rydberg-atom based electromagnetic field detector of the Rydberg-atom based electromagnetic field detector array further varies the transparency of the probe signal at that variable transparency unit so as to cause a detectable change in power of the probe signal at the optical receiver.

8. A method of operating an electromagnetic field detector, the electromagnetic field detector comprising the Rydberg-atom based electromagnetic field detector array as claimed in claim 1, the method comprising:
monitoring a probe signal, wherein the probe signal and a coupling signal have been transmitted along the Rydberg-atom based electromagnetic field detector array at a probe frequency and coupling frequency respectively, wherein the probe frequency and the coupling frequency are set to vary the transparency of the probe signal at each variable transparency unit of each Rydberg-atom based electromagnetic field detector of the Rydberg-atom based electromagnetic field detector array by the EIT effect and so that an electromagnetic field incident at a variable transparency unit of a Rydberg-atom based electromagnetic field detector of the Rydberg-atom based electromagnetic field detector array further varies the transparency of the probe signal at that variable transparency unit so as to cause a detectable change in power of the probe signal at the optical receiver;
detecting an attenuation event as a sequence of one or more probe signal portions at a first power level and one or more probe signal portions at a second power level; and
identifying a Rydberg-atom based electromagnetic field detector of the Rydberg-atom based electromagnetic field detector array by correlating the sequence of one or more probe signal portions at a first power level and one or more probe signal portions at a second power level of the detected attenuation event with the unique sequence of one or more variable transparency units and one or more separator units of the plurality of units for the Rydberg-atom based electromagnetic field detector.

9. The method as claimed in claim 8, further comprising:
identifying a plurality of Rydberg-atom based electromagnetic field detectors of Rydberg-atom based electromagnetic field detector array, wherein at least one of the plurality of Rydberg-atom based electromagnetic field detectors is identified by correlating the sequence of one or more probe signal portions at a first power level and one or more probe signal portions at a second power level of the detected attenuation event with the unique sequence of one or more variable transparency units and one or more separator units of the plurality of units for the Rydberg-atom based electromagnetic field detector; and
determining a location of the transmitter of the electromagnetic field based on the identified plurality of Rydberg-atom based electromagnetic field detectors.

10. The method as claimed in claim 9, further comprising:
determining a distance between each of the identified plurality of Rydberg-atom based electromagnetic field detectors and a transmitter of the electromagnetic field,
wherein the location of the transmitter of the electromagnetic field is based on the determined distances between each of the identified plurality of Rydberg-atom based electromagnetic field detectors and the transmitter of the electromagnetic field.

11. The method as claimed in claim 9, wherein determining the location of the transmitter is based on a machine-learning technique.

12. A computer program comprising instructions which, when the computer program is executed by the electromagnetic field detector of claim 7, cause the electromagnetic field detector to operate the electromagnetic field detector comprising the Rydberg-atom based electromagnetic field detector array by:
monitoring a probe signal, wherein the probe signal and a coupling signal have been transmitted along the Rydberg-atom based electromagnetic field detector array at a probe frequency and coupling frequency respectively, wherein the probe frequency and the coupling frequency are set to vary the transparency of the probe signal at each variable transparency unit of each Rydberg-atom based electromagnetic field detector of the Rydberg-atom based electromagnetic field detector array by the EIT effect and so that an electromagnetic field incident at a variable transparency unit of a Rydberg-atom based electromagnetic field detector of the Rydberg-atom based electromagnetic field detector array further varies the transparency of the probe signal at that variable transparency unit so as to cause a detectable change in power of the probe signal at the optical receiver;
detecting an attenuation event as a sequence of one or more probe signal portions at a first power level and one or more probe signal portions at a second power level; and
identifying a Rydberg-atom based electromagnetic field detector of the Rydberg-atom based electromagnetic field detector array by correlating the sequence of one or more probe signal portions at a first power level and one or more probe signal portions at a second power level of the detected attenuation event with the unique sequence of one or more variable transparency units and one or more separator units of the plurality of units for the Rydberg-atom based electromagnetic field detector.

13. A non-transitory computer readable carrier medium comprising the computer program of claim 12.
